(19) United States
(12) Patent Application Publication
(10) Pub. No.: US 2026/0362999 A1
(43) Pub. Date: Nov. 12, 2026

(54) SUBSTRATE ETCHING METHOD AND DEVICE

(71) Applicants: ACM RESEARCH (SHANGHAI), INC., Shanghai (CN); ACM Research (Lingang), Inc., Shanghai (CN)

(72) Inventors: Hui Wang, Shanghai (CN); Rong Xu, Shanghai 201203 (CN); Jun Wang, Shanghai (CN); Yazhou Li, Shanghai (CN); Xiaoyan Zhang, Shanghai (CN)

(73) Assignees: ACM RESEARCH (SHANGHAI), INC., Shanghai (CN); ACM Research (Lingang), Inc., Shanghai (CN)

(21) Appl. No.: 19/477,082

(22) PCT Filed: Mar. 20, 2024
(86) PCT No.: PCT/CN2024/082820

§ 371 Date: Oct. 20, 2025

(30) Foreign Application Priority Data
Apr. 19, 2023 (CN) 202310424800.5

(51) Int. Cl. H10P 50/68; H10P 72/00

(52) U.S. Cl. CPC H10P 50/683; H10P 72/0426

(57) ABSTRACT

The present invention discloses a substrate etching method and apparatus. The substrate etching method comprises: immersing a substrate into a processing tank containing an etching solution and performing wet etching on the substrate using the etching solution, wherein a deep structure is formed on the surface of the substrate; and supplying a gas into the etching solution based on a pulse signal to generate bubbles in the etching solution, wherein one pulse period of the pulse signal comprises a gas-supply period and an idle period, and the idle period depends on the diffusion time required for a key component inside the deep structure to reach diffusion equilibrium after the gas-supply period ends.

### FIELD OF THE INVENTION

The present invention relates to the field of semiconductor manufacturing, and in particular to a substrate etching method and apparatus.

### BACKGROUND

Wet etching is a process in which a substrate is immersed into an etching solution, and the etching solution is used to perform chemical etching on a thin film to be removed. During wet etching, a gas is usually supplied into the etching solution to generate bubbles in order to improve etching performance. At present, the industry is dedicated to optimizing the flow rate and distribution of the supplied gas to achieve a better etching rate and uniformity. Improvements in etching uniformity generally focus on enhancing within-substrate etching uniformity and substrate-to-substrate etching uniformity.

However, when wet etching is performed on a thin film inside a deep structure on a substrate, for example, when wet etching is performed on a silicon-nitride film inside a deep structure such as a narrow gap, a narrow trench, and/or a high-aspect-ratio via formed on a substrate, the etching uniformity inside the deep structure will also become a key factor affecting the reliability of a semiconductor device. Compared with the top of the deep structure, the bottom of the deep structure provides lower macroscopic flow and mass-transfer efficiency, causing the concentrations of etching products and etching reactants to differ at the top and the bottom of the deep structure and thus forming a concentration gradient. The larger the aspect ratio of the deep structure is, the steeper the concentration gradient inside the deep structure is. In this case, the etching difference at different locations inside the deep structure increases, affecting the etching uniformity inside the deep structure.

Therefore, it is necessary to improve wet etching so as to control the etching uniformity inside the deep structure.

### SUMMARY

In view of the above drawbacks of the prior art, an object of the present invention is to provide a substrate etching method and apparatus for solving the problem of non-uniform etching inside a deep structure of a substrate in the prior art.

To achieve the above and other related objects, the present invention provides a substrate etching method, comprising:
immersing a substrate into a processing tank containing an etching solution and performing wet etching on the substrate using the etching solution, wherein a deep structure is formed on the surface of the substrate;
supplying a gas into the etching solution based on a pulse signal to generate bubbles in the etching solution, wherein one pulse period of the pulse signal comprises a gas-supply period and an idle period, the idle period depends on the diffusion time required for a key component inside the deep structure to reach diffusion equilibrium after the gas-supply period ends.

Optionally, the interval time T_{g} between adjacent bubbles generated during the gas-supply period is shorter than the diffusion time Tai required for the key component inside the deep structure to reach diffusion equilibrium after the disturbance caused by the preceding bubble in the adjacent bubbles.

Optionally, the gas is supplied continuously into the etching solution during the gas-supply period.

Optionally, the gas is supplied into the etching solution intermittently based on N sub-pulse signals during the gas-supply period, each sub-pulse signal generates one bubble correspondingly, and N is a natural number equal to or smaller than 10.

In another aspect, the present invention further provides a substrate etching apparatus comprising:
a processing tank, for containing an etching solution;
a holding mechanism, for holding a substrate and immersing the substrate into the etching solution, wherein a deep structure is formed on the surface of the substrate;
a gas-supply unit, for supplying a gas into the etching solution to generate bubbles for disturbing the etching solution; and
a controller, configured to control the gas-supply unit to supply the gas into the etching solution based on a pulse signal, one pulse period of the pulse signal comprises a gas-supply period and an idle period, the idle period depends on the diffusion time required for a key component inside the deep structure to reach diffusion equilibrium after the gas-supply period ends.

As described above, the substrate etching method and apparatus provided by the present invention have the following beneficial effects:
1. During wet etching, a gas is supplied into an etching solution in a pulsed manner, one pulse period comprises a gas-supply period and an idle period, and the idle period is determined according to the diffusion time required for a key component inside a deep structure to reach diffusion equilibrium after the gas-supply period ends, so that the interval of disturbance to a trench between adjacent gas-supply periods is properly controlled and the degree of diffusion in the trench is regulated, thereby improving the etching uniformity in the trench;
2. By making the interval time between adjacent bubbles generated during the gas-supply period shorter than the diffusion time required for the key component in the deep structure to reach diffusion equilibrium after the disturbance caused by the preceding bubble in the adjacent bubbles, the superposed disturbance of a plurality of bubbles is utilized to enhance the disturbance intensity during the gas-supply period so as to enlarge the convection region in the deep structure and increase the mass-transfer efficiency in the deep structure;
3. During the gas-supply period, the single-bubble pulse mode in which the gas is supplied into the etching solution intermittently based on N sub-pulse signals not only effectively controls the generation time of each individual bubble and therefore precisely controls the interval time between adjacent bubbles, but also adopts a higher gas flow rate to obtain bubbles with higher velocity, further enhancing the disturbance of the bubbles.

### BRIEF DESCRIPTION OF THE DRAWINGS

The features and performance of the present invention will be further described by the following embodiments and the accompanying drawings of the embodiments.

FIG. 1 shows a schematic view of a wet-etching apparatus;

FIG. 2 shows a schematic structural view of a portion of a 3D NAND flash device, and the 3D NAND flash device has a stack layer and a trench penetrating the stack layer;

FIG. 3 shows a diagram describing the etching rate of SiO₂ varying with the silicon concentration in a reaction system;

FIG. 4 shows a schematic view of SiO₂ redeposition and the over-etching of a silicon-oxide film in the trench;

FIG. 5 shows a schematic view of suppression upon the diffusion of a key component in the trench by a subsequent bubble after the disturbance caused by a preceding bubble;

FIG. 6 shows a timing diagram of the pulse signal in Embodiment 1 of the present application;

FIG. 7 shows a schematic view of the superposition effect of adjacent bubbles;

FIG. 8 shows a timing diagram of the pulse signal in Embodiment 2 of the present application; and

FIG. 9 shows a timing diagram of the pulse signal in another embodiment of the present application.

### EMBODIMENTS OF THE INVENTION

Hereinafter, the embodiments of the present invention will be described through specific examples. Those in the art can easily understand other advantages and effects of the present invention from the content disclosed in the specification. The present invention can also be implemented or applied through other different specific embodiments, and various modifications or alterations can be made to details in the specification without departing from the spirit of the present invention.

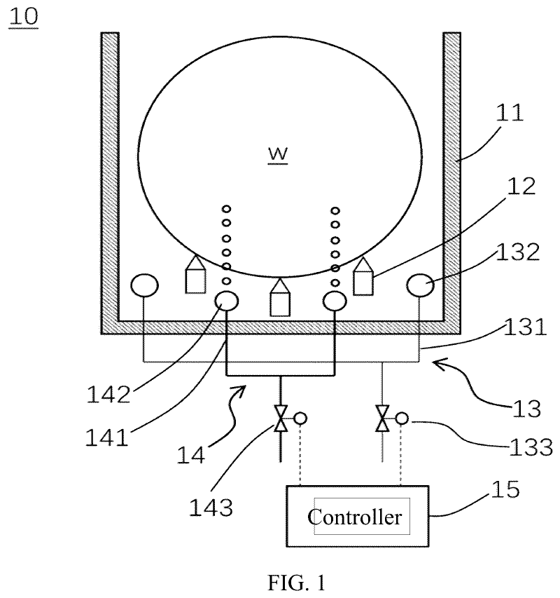

Please refer to FIGS. 1-9. It should be noted that the diagrams provided in these embodiments only schematically illustrate the basic concept of the present invention. The diagrams only show components related to the present invention rather than being drawn according to the number, shape, and size of the components in actual implementation. The form, quantity, and proportion of each component in actual implementation can be altered arbitrarily, and the component layout form may also be more complex.

The substrate etching method of the present application is applicable to etching substrates with deep structures in a wet-etching apparatus performing batch processing. FIG. 1 shows an exemplary wet-etching apparatus (i.e., substrate etching apparatus) for implementing the substrate etching method of the present application. As shown in FIG. 1, the wet-etching apparatus 10 comprises a processing tank 11 for containing an etching solution; a holding mechanism 12 for holding a substrate W and immersing the substrate W into the etching solution; a liquid-supply unit 13 for supplying the etching solution into the processing tank; a gas-supply unit 14 for supplying a gas into the etching solution to generate bubbles for disturbing the etching solution; and a controller 15. Wherein, the liquid-supply unit 13 comprises a liquid-supply line 131 and a liquid nozzle 132. The liquid nozzle 132 is arranged inside the processing tank 11 and located below the substrate W. A liquid regulating valve 133 is disposed on the liquid-supply line 131. The gas-supply unit 14 comprises a gas-supply line 141 and a gas nozzle 142. The gas nozzle 142 is arranged in the processing tank 11 and located below the substrate W. A gas regulating valve 143 is disposed on the gas-supply line 141. The controller 15 controls the flow rate of the gas supplied to the gas nozzle 142 via the gas-supply line 141 by controlling the operation of the gas regulating valve 143, and controls the flow rate of the liquid supplied to the liquid nozzle 132 via the liquid-supply line 131 by controlling the operation of the liquid regulating valve 132.

In order to solve the problem of non-uniform etching in the deep structure of the substrate, the present application proposes a substrate etching method comprising the steps of immersing the substrate W into the processing tank 11 containing the etching solution and performing the steps of wet etching on the substrate W using the etching solution; and supplying the gas into the etching solution based on a pulse signal to generate bubbles in the etching solution during wet etching. In the present application, according to FIG. 1, the controller 15 controls the operation of the gas regulating valve 143 based on the pulse signal to supply pulsed gas to the gas nozzle 142. Wherein, one pulse period of the pulse signal comprises a gas-supply period and an idle period, wherein the idle period depends on the diffusion time required for a key component in a trench to reach diffusion equilibrium after the gas-supply period ends. Specific settings of the pulse signal will be described later and will not be repeated here. In addition, it should be noted that the key component refers to the main component in a reaction system that affects the etching uniformity, including etching reactants and/or etching products.

Hereinafter, taking wet etching for selectively removing a silicon-nitride film on a stack layer using a phosphoric acid solution during the manufacturing of a 3D NAND flash device as an example, the phenomenon and cause of non-uniform etching in a trench will be described in detail so as to facilitate the understanding of the substrate etching method proposed in the present application.

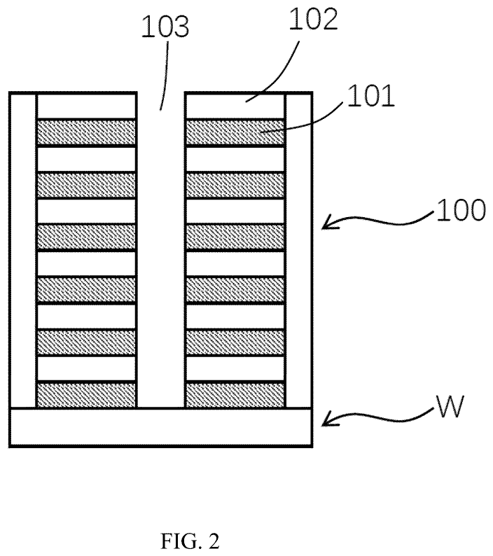

FIG. 2 exemplarily shows a partial structure of the 3D NAND flash device. As shown in FIG. 2, the structure comprises a stack layer 100 formed on the substrate W and a trench 103 penetrating the stack layer 100, wherein the stack layer 100 is formed by the alternating deposition of a silicon-nitride film 101 and a silicon-oxide film 102. In this example, the trench 103 on the stack layer 100 is a deep structure formed on the substrate W. During the manufacturing of the 3D NAND flash device, the silicon-nitride film 101 on the stack layer 100 needs to be removed. Generally, wet etching is performed on the substrate using the phosphoric acid solution (etching solution) to selectively remove the silicon-nitride film 101 on the stack layer 100.

In the phosphoric acid solution, silicon nitride (Si₃N₄) undergoes a chemical reaction shown in equation (1):

Si₃N₄+H₃PO₄+H₂O→NH₄H₂PO₄+Si(OH)₄ (1)

In the phosphoric acid solution, silicon oxide (SiO₂) undergoes a chemical reaction shown in equation (2):

SiO₂+H₂O [symbol] Si(OH)₄ (2)

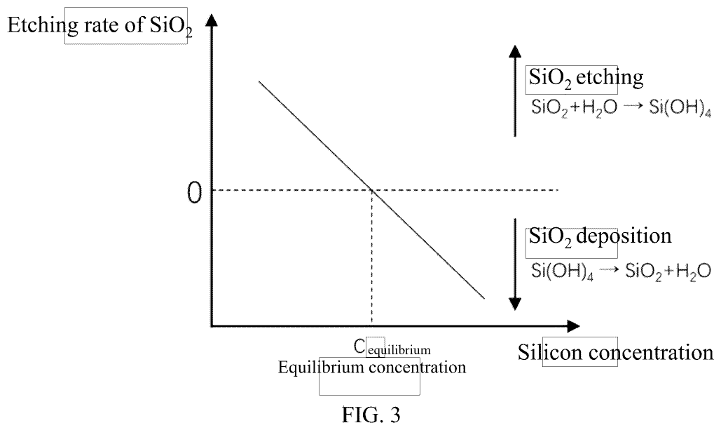

Equation (2) is a reversible reaction, and the reaction direction of the equation (2) is controlled by adjusting the silicon concentration (e.g., Si(OH)₄ concentration) in a reaction system. FIG. 3 shows a diagram describing the etching rate of SiO₂ varying with the silicon concentration in the reaction system. According to FIG. 3, when the silicon concentration is at an equilibrium concentration, the reversible reaction of the equation (2) reaches equilibrium and the etching rate of SiO₂ is zero; when the silicon concentration is below the equilibrium concentration, the reversible reaction of the equation (2) proceeds to the right, the etching rate of SiO₂ is greater than zero, SiO₂ hydrolyzes to form Si(OH)₄, and the etching reaction of SiO₂ occurs; when the silicon concentration is above the equilibrium concentration, the reversible reaction of the equation (2) proceeds to the left, the etching rate of SiO₂ is smaller than zero, Si(OH)₄ polymerizes to form SiO₂, and the deposition reaction of SiO₂ occurs. In addition, since the silicon concentration has little effect on the etching rate of Si₃N₄, the etching selectivity of phosphoric acid to silicon nitride and silicon oxide can be controlled by adjusting the silicon concentration in the phosphoric acid solution. Typically, the silicon concentration in the phosphoric acid solution is slightly lower than the equilibrium concentration. Taking a 160° C. phosphoric acid solution as the etching solution as an example, the equilibrium silicon concentration is 80 ppm, and the silicon concentration process window for the phosphoric acid solution is set to a value within the range of about 40 ppm to 70 ppm.

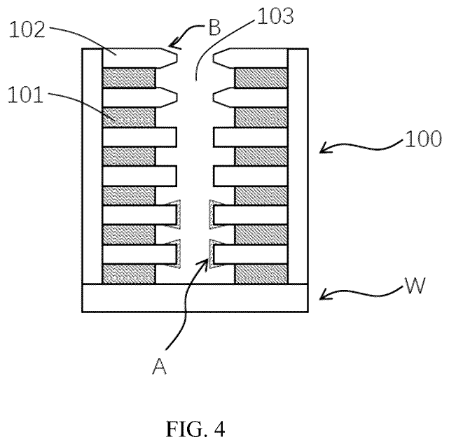

According to the above equation (1), an etching product Si(OH)₄ is generated during the etching of the silicon-nitride film 101 in the trench 103, and the diffusion efficiency of the etching product Si(OH)₄ will affect the silicon concentration distribution in the trench 103. When the silicon concentration in a localized region of the trench 103 exceeds the equilibrium concentration, the deposition reaction of SiO₂ will occur in the localized region (as shown in the chemical equation (2) and FIG. 3), and the generated SiO₂ deposition product adheres to the silicon-oxide film 102, causing SiO₂ redeposition; when the silicon concentration in a localized region of the trench 103 is lower than the equilibrium concentration, the etching reaction of SiO₂ will occur in the localized region (as shown in the chemical equation (2) and FIG. 3), and when the etching amount of the silicon-oxide film 102 exceeds process requirements, the silicon-oxide film 102 will be over-etched. Both the above-mentioned SiO₂ redeposition and over-etching of the silicon-oxide film 102 are manifestations of non-uniform etching in the trench 103, and such non-uniform etching will affect the performance and reliability of a product and is therefore undesirable. In comparison, the silicon concentration is low at the top of the trench 103, and the over-etching of the silicon-oxide film 102 is prone to occur; the silicon concentration is high at the bottom of the trench 103, and SiO₂ redeposition is prone to occur. In FIG. 4, A shows SiO₂ redeposition at the bottom of the trench 103, and B shows the over-etching of the silicon-oxide film 102 at the top of the trench 103, wherein the silicon-nitride film 101 is partially etched.

The storage capacity of a 3D NAND flash device is generally quantified by the number of layers on the stack layer 100. Currently, the stack layer 100 of a 3D NAND flash device can have 64 layers, 96 layers, 128 layers, or even more layers. The more layers the stack layer 100 has, the larger the aspect ratio of the trench 103 is and the more difficult mass transfer in the trench 103 is. This causes the etching product Si(OH)₄ of the silicon-nitride film 101 to accumulate in the trench 103, especially at the bottom of the trench 103, increasing the risk of SiO₂ redeposition in the trench 103. Therefore, as the aspect ratio of the trench 103 increases, the challenge of uniform etching in the trench 103 becomes greater.

At present, a common method for improving the etching uniformity in the trench 103 is to supply a gas continuously into the phosphoric acid solution to generate continuous bubbles, thereby increasing the liquid flow velocity on the surface of the substrate W to promote the mass transfer efficiency in the trench 103, and to continuously increase the gas flow rate as the aspect ratio of the trench 103 increases, in an attempt to achieve better etching uniformity.

In practice, if the trench 103 has a low aspect ratio, bubbles generated by a low gas flow rate can effectively improve the mass transfer efficiency in the trench 103. However, if the trench 103 has a high aspect ratio, for example, when the aspect ratio of the trench 103 exceeds 40:1, the effect of bubbles generated by a low gas flow rate on promoting the mass transfer efficiency in the trench 103, especially at the bottom of the trench 103, is weak. Due to the low mass transfer efficiency, the etching product Si(OH)₄ accumulates at the bottom of the trench 103, increasing the risk of SiO₂ redeposition at the bottom of the trench 103. In order to overcome the problem of SiO₂ redeposition at the bottom of the trench 103, the gas flow rate can be increased to generate more bubbles with higher velocity, thereby enhancing the promotion of the mass transfer efficiency in the trench 103 and reducing the risk of SiO₂ redeposition at the bottom of the trench 103. However, it should be noted that although increasing the gas flow rate helps reduce the silicon concentration at the bottom of the trench 103 and improve SiO₂ redeposition at the bottom of the trench 103, at the same time, a high gas flow rate will also cause the silicon concentration near the top of the trench 103 to drop too rapidly, increasing the risk of over-etching of the silicon-oxide film 102 at the top of the trench 103. Therefore, in the continuous gas-supply mode, as the aspect ratio of the trench 103 continues to increase, simply increasing the gas flow rate cannot effectively solve the problem of non-uniform etching in the trench 103.

In addition, in practice, the applicant has also found that bubble interval time is also an important factor affecting the diffusion of substances in the trench 103. Specifically, if the interval between adjacent bubbles is shorter than the diffusion time required for the etching product Si(OH)₄ in the trench 103 to reach diffusion equilibrium after the disturbance caused by the preceding bubble in the adjacent bubbles, the outward diffusion of the etching product Si(OH)₄ in the trench 103 may be suppressed.

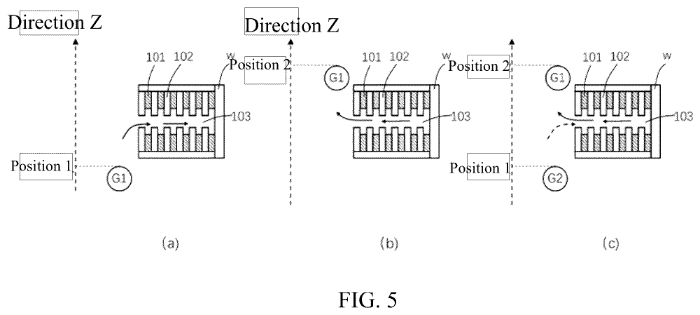

To facilitate understanding, the above discovery will be briefly explained below with reference to FIG. 5. In FIG. 5, positions 1 and 2 by which a bubble passes along the ascending direction Z are shown, wherein the position 1 approximately indicates a position where the bubble is approaching the trench 103, and the position 2 approximately indicates a position where the bubble is leaving the trench 103, and both the positions 1 and 2 are within the range of disturbance caused by the bubble to the trench 103. It should be noted that the flow field in the trench 103 in FIG. 5 is simplified and is not the actual flow field in the trench 103.

FIG. 5(a) shows the effect of a bubble G1 on the flow field in the trench 103 when the bubble G1 passes by the position 1. FIG. 5(b) shows the effect of the bubble G1 on the flow field in the trench 103 when the bubble G1 passes by the position 2. In FIG. 5(a), when the bubble G1 passes by the position 1, the bubble G1 is about to approach the trench 103 and squeezes the etching solution outside the trench 103 into the trench 103, causing the flow field in the trench 103 to exhibit a trend to flow from the outside of the trench 103 to the inside of the trench 103, which is conducive to the diffusion of fresh phosphoric acid solution into the trench 103. In FIG. 5(b), when the bubble G1 passes by the position 2, the bubble G1 is leaving the trench 103, and the inward squeezing effect of the bubble G1 on the liquid in the trench 103 begins to disappear. In this case, the liquid pressure in the trench 103 is released, causing the flow field in the trench 103 to exhibit a trend to flow from the inside of the trench 103 to the outside of the trench 103. The spent phosphoric acid solution inside the trench 103 diffuses toward the outside of the trench 103, which is conducive to the diffusion of the etching product Si(OH)₄ in the trench 103 to the outside of the trench 103. Therefore, the disturbance of the bubble to the trench 103 includes two stages: squeezing the liquid inward and releasing the liquid outward.

FIG. 5(c) shows the effect on the flow field in the trench 103 when a subsequent bubble G2 passes by the position 1 while the bubble G1 is passing by the position 2. In FIG. 5(c), when the bubble G1 is at the position 2, an outward flow field (indicated by the solid arrows in FIG. 5(c)) conducive to the diffusion of the etching product Si(OH)₄ to the outside of the trench 103 is generated in the trench 103. The etching product Si(OH)₄ needs a certain period of time to reach diffusion equilibrium. If, at this moment, the subsequent bubble G2 is already in an inward flow field conducive to the diffusion of the fresh phosphoric acid solution into trench 103 (indicated by the dashed arrow in FIG. 5(c)), for example, when the bubble G2 is at the position 1, then in an opening region near the trench 103, the inward flow field will hinder the outward flow field or even force the outward flow field to reverse the direction, thereby suppressing the diffusion of the etching product Si(OH)₄ in the trench 103 toward outside of the trench 103. If the outward diffusion of the etching product Si(OH)₄ in the trench 103 is always suppressed, the etching product Si(OH)₄ will accumulate in the trench 103, causing SiO₂ redeposition. Therefore, properly controlling the interval between adjacent bubbles can allow enough time for the etching product Si(OH)₄ in the trench 103 to fully diffuse. This is conducive to improving the replacement efficiency of the etching product Si(OH)4, improving the silicon concentration distribution in the trench 103, and thereby improving the etching uniformity in the trench 103.

In view of the above analysis, in the substrate etching method proposed in the present application, when a substrate is immersed into an etching solution for wet etching, a gas is supplied into the etching solution based on a pulse signal. One pulse period of the pulse signal comprises a gas-supply period and an idle period. The idle period is determined according to the diffusion time required for a key component in the trench 103 to reach diffusion equilibrium after the gas-supply period ends, so that the interval of disturbance to the trench 103 between adjacent gas-supply periods is properly controlled and the degree of diffusion in the trench 103 is regulated, thereby improving the etching uniformity in the trench 103. It should be noted that the pulse signal can be applied to the entire process time for substrate etching or only to a portion of the process time for substrate etching.

Hereinafter, taking the application of the substrate etching method proposed in the present application to the wet etching for selectively removing the silicon-nitride film 101 on the stack layer 100 using the phosphoric acid as an example, specific embodiments of the substrate etching method proposed in the present application will be described. The key component affecting the etching uniformity is the etching product Si(OH)₄.

### Embodiment 1

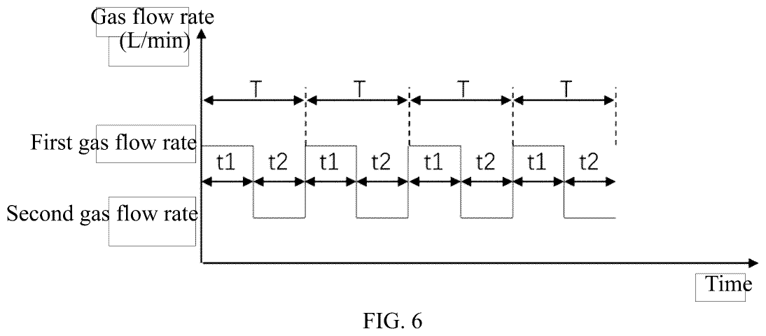

FIG. 6 shows a timing diagram of the pulse signal in Embodiment 1 of the present application. As shown in FIG. 6, one pulse period T of the pulse signal comprises a gas-supply period t1 and an idle period t2. In some embodiments, the gas-supply period t1 can be set to a value within the range of 10 ms to 1 s; the idle period t2 can also be set to a value within the range of 10 ms to 1 s. The idle period t2 depends on the diffusion time T_{d2} required for a key component in the trench 103 to reach diffusion equilibrium after the gas-supply period t1 ends. Preferably, the value of the idle period t2 is proportional to the diffusion time T_{d2}, denoted as t2=k*T_{d2}, where k is greater than 0 and is a set value, and T_{d2} is an experimentally measured value or a computational simulation value, that is, T_{d2} can be obtained through experiments or computational simulations.

During the wet etching of a silicon-nitride film 101 on a stack layer 100, k can be set to a value no smaller than 0.5, for example, k can be set to a value within the range of 0.5 to 2, or 0.6 to 1, so that an etching product Si(OH)₄ in a trench 103 has sufficient time to diffuse outward between two adjacent gas-supply periods t1. This not only enhances mass diffusion in the trench 103 via the disturbance formed in a preceding gas-supply period t1, but also prevents the disturbance formed in a subsequent gas-supply period t1 from suppressing the mass diffusion in the trench 103, so that the mass diffusion in the trench 103 is sufficient, the diffusion efficiency in the trench 103 is improved, and the silicon concentration gradient in the trench 103 is reduced. A lower silicon concentration gradient not only lowers the silicon concentration in the trench 103, especially at the bottom of the trench 103, to suppress SiO₂ redeposition at the bottom of the trench 103, but also increases the silicon concentration at the top of the trench 103 to improve the over-etching of a silicon-oxide film 102 at the top of the trench 103.

It should be noted that the above value of k in the wet etching of the silicon-nitride film 101 on the stack layer 100 is only an example. The setting range of the value of k can be properly adjusted according to the object of wet etching and actual process conditions. For example, in some wet etching processes, k may also be set to a value smaller than 0.5.

During the gas-supply period t1, a gas is supplied into an etching solution at a first gas flow rate, and during the idle period t2, the gas is supplied into the etching solution at a second gas flow rate. The first gas flow rate is greater than the second gas flow rate, so as to generate bubbles in the etching solution and disturb localized regions on the substrate surface, for example, the surface of the trench 103, to enhance mass transfer in the trench 103. The second gas flow rate can be set to zero or to a value greater than zero, mainly to prevent the etching solution from flowing back into the gas nozzle. The minimum gas flow rate required to prevent the etching solution from flowing back into the gas nozzle is defined as a critical gas flow rate, and the second gas flow rate can be set to a value no lower than the critical gas flow rate.

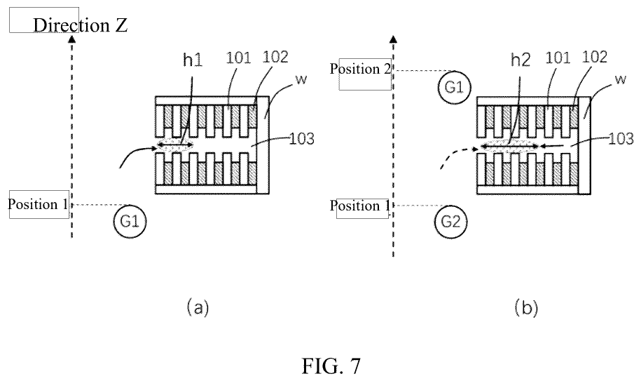

The number of bubbles generated in the etching solution by the gas supplied during the gas-supply period t1 is N, and N is a natural number equal to or smaller than 10. For example, the number of bubbles generated during the gas-supply period t1 is 1, 2, 3, or more. All the bubbles generated during the gas-supply period t1 form a bubble group, and the interval time T_{g} between adjacent bubbles in the bubble group depends on the diffusion time T_{d1} required for the key component in the trench 103 to reach diffusion equilibrium after the disturbance caused by the preceding bubble in the adjacent bubbles. In order to enhance the overall disturbance effect of the bubble group, the interval time T_{g} between adjacent bubbles in the bubble group should be shorter than the diffusion time T_{d1} required for the key component in the trench 103 to reach diffusion equilibrium after the disturbance caused by the preceding bubble, that is, T_{g} is smaller than T_{d1}. Preferably, T_{g}=k₁*T_{d1}, k₁∈(0,0.5). In this way, before the end of the release effect generated by the preceding bubble for promoting the outward diffusion of the etching product in the trench 103, the squeezing effect generated by the subsequent bubble for hindering the outward diffusion of the etching product has already begun, so that the disturbance effects of the adjacent bubbles in the bubble group to the liquid in the trench 103 are superposed, enhancing the disturbance to the etching solution during the gas-supply period t1, effectively improving the mass transfer efficiency in the trench 103, and helping to shorten the etching process time. The principle of the superposition effect of adjacent bubbles will be explained below with reference to FIG. 7. As shown in FIG. 7(a), when the bubble G1 is at position 1, the bubble G1 squeezes fresh etching solution outside the trench 103 into the trench 103, and the disturbance depth of the liquid in the trench 103 is h1; as shown in FIG. 7(b), when the bubble G1 moves to position 2, the squeezing force exerted by the bubble G1 on the inside of the trench 103 is about to be released or has not been completely released, and the liquid inside the trench 103 tends to flow outward (indicated by the solid arrows in FIG. 7(b)), that is, the etching product, for example, Si(OH)₄, inside the trench 103 is at an outward diffusion stage. However, the etching product Si(OH)₄ needs a certain period of time to reach diffusion equilibrium. Assuming that the interval between the bubbles G1 and G2 is shorter than the diffusion time required for the etching product Si(OH)₄ in the trench 103 to reach diffusion equilibrium after the disturbance caused by the bubble G1, then before the etching product Si(OH)₄ reaches diffusion equilibrium after the disturbance caused by the bubble G1, the bubble G2 has already moved to a position (e.g., position 1) where the bubble G2 squeezes another fresh etching solution outside the trench 103 into the trench 103 (indicated by the dashed arrow in FIG. 7(b)), and the bubble G2 will push the disturbance depth of the liquid in the trench 103 forward to h2.

In other words, during the gas-supply period t1, it is desired to reduce the interval between adjacent bubbles, so that the squeezing effects of a plurality of bubbles that force the fresh etching solution outside the trench 103 into the trench 103 are superposed, so as to increase the disturbance depth of the liquid in the trench 103 as much as possible, increase the concentration of an etching reactant, for example, H₃PO₄, in the trench 103, increase the etching rate of the silicon-nitride film 101, and promote the mass transfer deep into the trench 103, especially at the bottom of the trench 103, by enhancing internal disturbance in the trench 103. Under ideal conditions, forced convection is formed between the top and the bottom of the trench 103. During the idle period t2, an appropriate period of time is desired to allow the etching product, for example, Si(OH)₄, inside the trench 103 to diffuse outward.

Again, according to FIG. 6, in Embodiment 1, the gas is continuously supplied into the etching solution during the gas-supply period t1. When the gas is continuously supplied during the gas-supply period t1, the first gas flow rate is preferably a value within the range of 0.5 L/min to 2 L/min.

### Embodiment 2

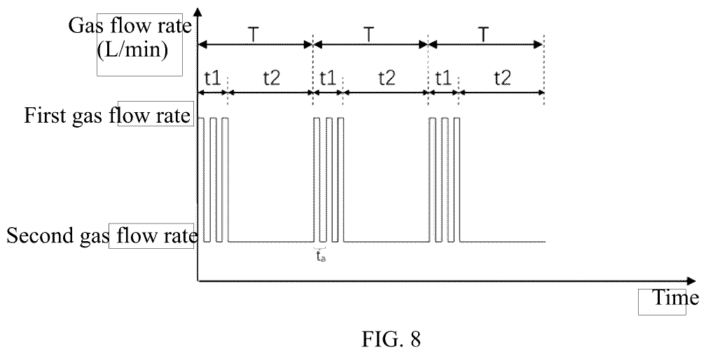

As shown in FIG. 8, a substrate etching method is proposed in this embodiment. Compared with Embodiment 1, Embodiment 2 is different in that a gas is supplied into an etching solution intermittently during a gas-supply period t1 based on N sub-pulse signals, each sub-pulse signal generates one bubble correspondingly, and N is a natural number equal to or smaller than 10.

FIG. 8 shows a timing diagram of the pulse signal in Embodiment 2 of the present application. As shown in FIG. 8, one pulse period T of the pulse signal comprises a gas-supply period t1 and an idle period t2. In FIG. 8, each gas-supply period t1 comprises 3 sub-pulse signals, and each sub-pulse signal generates one bubble correspondingly within the pulse period ta of the sub-pulse signal, referred to as a single-bubble pulse. The single-bubble pulse can effectively control the generation time of each individual bubble, thereby precisely controlling the interval between adjacent bubbles. In this embodiment, the pulse period ta of the single-bubble pulse can be approximately regarded as the interval time T_{g} between adjacent bubbles. The pulse period of the sub-pulse signals can be set to, for example, a value within the range of 10 ms to 100 ms.

The single-bubble pulse can also utilize a higher gas flow rate to generate bubbles with higher velocity, thereby achieving better disturbance effects on the etching solution. In an example, the flow rate of the gas supplied into the etching solution by the sub-pulse signals is set to no lower than 2 L/min, for example, 2 L/min to 30 L/min, preferably 5 L/min to 20 L/min. Specifically, the flow rate of the gas supplied into the etching solution by the sub-pulse signals can be set to 2.5 L/min, 3 L/min, 10 L/min, 15 L/min, etc.

It should be noted that, compared with the upper limit of the gas flow rate that can be used in the continuous gas-supply mode in Embodiment 1, the upper limit of the gas flow rate that can be used in the single-bubble pulse mode during the gas-supply period in Embodiment 2 is higher, because when the continuous gas-supply mode is adopted for the gas-supply period, when the gas flow rate exceeds a certain range, for example, the gas flow rate is 5 L/min, the supplied gas may form a gas column not conducive to etching in the etching solution.

It should be noted that the substrate etching method proposed in the present application is not only applicable to the removal of a silicon-nitride film 101 on a stack layer 100 of a 3D NAND device, but also applicable to the removal of a thin film inside a deep structure such as a narrow gap, a narrow trench, and a high-aspect-ratio via formed on a logic device, an interconnect structure, a fin field-effect transistor (FinFET), a 3D semiconductor structure, etc.

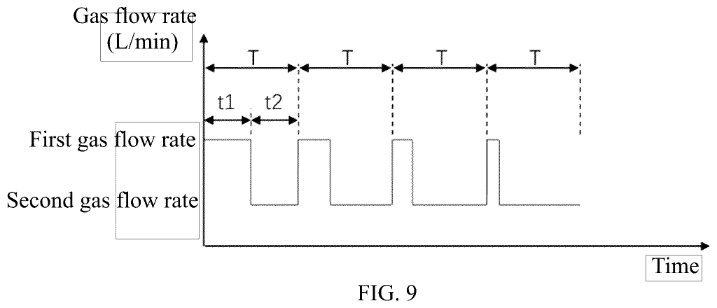

In addition, in the substrate etching method proposed in the present application, the pulse signal can be periodic or non-periodic. Specifically, duty cycle, frequency, and amplitude of the pulse signal can be fixed or adjusted according to actual processes, wherein the duty cycle refers to the proportion of the gas-supply period in one pulse period, and the amplitude corresponds to the flow rate of the supplied gas. For example, the pulse signal shown in FIGS. 6 and 8 is periodic, that is, the duty cycle, frequency, and amplitude of each pulse in the pulse signal are the same. In another example, the pulse signal shown in FIG. 9 is non-periodic, and the duty cycle of the pulse signal gradually decreases, that is, the proportion of the gas-supply period t1 in one pulse period T gradually decreases. It can be understood that when the gas is supplied into the etching solution using a non-periodic pulse signal, the number of bubbles generated in different gas-supply periods can be controlled by adjusting the duty cycle, frequency, and amplitude of the pulse signal. In addition, FIG. 9 shows only a specific example of a non-periodic pulse signal, and the non-periodic setting of the pulse signal in actual application can be properly set according to specific process conditions.

The above embodiments merely illustrate the principles and effects of the present invention by way of example, and are not intended to limit the present invention. Any person skilled in the art may modify or alter the above embodiments without departing from the spirit and scope of the present invention. Therefore, all equivalent modifications or alterations made by those with ordinary knowledge in the technical field without departing from the spirit and technical ideas disclosed in the present invention shall still be covered by the claims of the present invention.

What is claimed is:

1. A substrate etching method, comprising:
immersing a substrate into a processing tank containing an etching solution and performing wet etching on the substrate using the etching solution, wherein a deep structure is formed on the surface of the substrate;
supplying a gas into the etching solution based on a pulse signal to generate bubbles in the etching solution, wherein one pulse period of the pulse signal comprises a gas-supply period and an idle period, and the idle period depends on the diffusion time required for a key component inside the deep structure to reach diffusion equilibrium after the gas-supply period ends.

2. The substrate etching method according to claim 1, wherein the idle period is within the range of 10 ms to 1 s.

3. The substrate etching method according to claim 1, wherein the idle period is denoted as t2, the diffusion time required for the key component inside the deep structure to reach diffusion equilibrium after the gas-supply period ends is denoted as T_{d2}, and t2 is proportional to T_{d2} and is denoted as t2=k*T_{d2}, where k is greater than zero.

4. The substrate etching method according to claim 3, wherein k is no smaller than 0.5.

5. The substrate etching method according to claim 4, wherein the value of k is within the range of 0.5 to 2.

6. The substrate etching method according to claim 1, wherein during the gas-supply period, the gas is supplied into the etching solution at a first gas flow rate, during the idle period, the gas is supplied into the etching solution at a second gas flow rate, and the second gas flow rate is lower than the first gas flow rate.

7. The substrate etching method according to claim 6, wherein the second gas flow rate is zero.

8. The substrate etching method according to claim 6, wherein the processing tank is provided with a gas nozzle for supplying the gas into the etching solution to generate bubbles, the second gas flow rate is no lower than a critical gas flow rate, and the critical gas flow rate is the minimum gas flow rate required to prevent the etching solution from flowing back to the gas nozzle.

9. The substrate etching method according to claim 1, wherein the gas-supply period is within the range of 10 ms to 1 s.

10. The substrate etching method according to claim 1, wherein the number of bubbles generated during the gas-supply period is N, and N is a natural number equal to or smaller than 10.

11. The substrate etching method according to claim 10, wherein the interval time T_{g} between adjacent bubbles generated during the gas-supply period is shorter than the diffusion time T_{d1} required for the key component inside the deep structure to reach diffusion equilibrium after the disturbance caused by the preceding bubble in the adjacent bubbles.

12. The substrate etching method according to claim 11, wherein T_{g} =k₁*T_{d1}, and k₁∈(0, 0.5).

13. The substrate etching method according to claim 10, wherein the gas is continuously supplied into the etching solution during the gas-supply period.

14. The substrate etching method according to claim 13, wherein the flow rate of the gas supplied continuously into the etching solution is within the range of 0.5 L/min to 2 L/min.

15. The substrate etching method according to claim 10, wherein the gas is supplied into the etching solution intermittently based on N sub-pulse signals during the gas-supply period, each sub-pulse signal generates one bubble correspondingly, and N is a natural number equal to or smaller than 10.

16. The substrate etching method according to claim 15, wherein the pulse period of each of the sub-pulse signals is within the range of 10 ms to 100 ms.

17. The substrate etching method according to claim 15, wherein the flow rate of the gas supplied into the etching solution by the sub-pulse signals is no lower than 2 L/min.

18. The substrate etching method according to claim 17, wherein the flow rate of the gas supplied into the etching solution by the sub-pulse signals is within the range of 2 L/min to 30 L/min.

19. The substrate etching method according to claim 1, wherein the pulse signal is periodic or non-periodic.

20. A substrate etching apparatus, comprising:
a processing tank, for containing an etching solution;
a holding mechanism, for holding a substrate and immersing the substrate into the etching solution, wherein a deep structure is formed on the surface of the substrate;
a gas-supply unit, for supplying a gas into the etching solution to generate bubbles for disturbing the etching solution; and
a controller, configured to control the gas-supply unit to supply the gas into the etching solution based on a pulse signal, wherein one pulse period of the pulse signal comprises a gas-supply period and an idle period, and the idle period depends on the diffusion time required for a key component inside the deep structure to reach diffusion equilibrium after the gas-supply period ends.
